(19) United States
(12) Patent Application Publication
(10) Pub. No.: US 2024/0304732 A1
(43) Pub. Date: Sep. 12, 2024

(54) LOCALIZED AND LOW TEMPERATURE PLANARIZATION OF DIELECTRIC

(71) Applicants: THALES, Courbevoie (FR); COMMISSARIAT A L'ENERGIE ATOMIQUE ET AUX ENERGIES ALTERNATIVES, Paris (FR)

(72) Inventors: Grégory QUINCHARD, PALAISEAU (FR); Colin MISMER, PALAISEAU (FR)

(21) Appl. No.: 18/269,273

(22) PCT Filed: Dec. 23, 2021
(86) PCT No.: PCT/EP2021/087541

§ 371 Date: Jun. 22, 2023

(30) Foreign Application Priority Data
Dec. 23, 2020 (FR) 2014023

(51) Int. Cl. H01L 31/02; H01L 31/18

(52) U.S. Cl. CPC H01L 31/02005; H01L 31/18

(57) ABSTRACT

A method for fabricating a device includes the following steps: fabricating at least one first microstructure and one second microstructure on the substrate, fabricating a connection microstructure making it possible to electrically connect at least the first microstructure to the second microstructure by fabricating a support made of dielectric material by solidifying, by means of a lithography method, a part of a deposited resin layer and by depositing a first metallic layer on at least a part of the support comprising at least a part linking the first microstructure and the second microstructure.

### CROSS-REFERENCE TO RELATED APPLICATIONS

This application is a National Stage of International patent application PCT/EP2021/087541, filed on Dec. 23, 2021, which claims priority to foreign French patent application No. FR 2014023, filed on Dec. 23, 2020, the disclosures of which are incorporated by reference in their entireties.

### FIELD OF THE INVENTION

The invention relates to a planarization sub-method forming part of an overall microelectronic and/or microtechnical fabrication method making it possible to perform a localized planarization step based on a dielectric structure supporting metallic contacts. These metallic tracks link mutually leveled structures.

### BACKGROUND

Several fabrication techniques have been developed for producing microstructures and nanostructures on semiconductor substrates making it possible to fabricate integrated circuits and systems. These systems cover a multitude of uses such as transistor-based microelectronic circuits, microsystems of MEMS (micro-electro-mechanical systems) or NEMS (nano-electro-mechanical systems) types, integrated sensors (pressure sensors, accelerometers, chemical sensors, etc.), or photonic and optoelectronic systems incorporated on a semiconductor substrate.

More specifically, it is possible to produce hybrid systems combining two physical domains. The hybrid systems make it possible to associate two functionalities produced in different materials. Examples include:
a detector, in which the sensitive part is associated with a read circuit making it possible to harvest and process the signal to be detected,
a display, for example of light-emitting type, in which the emitting part is associated with a circuit for generating electrical signals suitable for emission,
a photonic circuit, with laser emitters associated with emitted beam processing layers (guiding, multiplexing/demultiplexing, amplification, etc.), the processing layer or layers being deposited on a silicon substrate (“photonic on silicon”),
an electronic circuit with fast or power transistors associated with a control system.

The first two hybrid systems can be qualified as optoelectronic, the third can be purely optical or optoelectronic, while the fourth is purely electronic.

With no loss of generality, all of the fabrication techniques used in the methods for the microtechnologies and nanotechnologies comprise the following technological steps:
Epitaxy: consisting of a technique of growth of a layer of materials on a substrate composed of another material.
Doping: consisting of the introduction of impurities through atoms in small quantities into a pure crystalline network to modify its electrical conductivity.
Heat treatment: consisting in increasing the temperature of a substrate in a controlled atmosphere in order to change its properties.
Deposition: consisting in depositing thin layers of material on the wafer supporting the device. It can be performed via a CVD (chemical vapor deposition) chemical method or a PVD (physical vapor deposition) physical method.
Lithography: a technique consisting in covering all of the surface of the wafer with a resin. The resin, being exposed to a beam through a mask, defines patterns that are the image of the mask or the reverse of the mask.
Etching: consisting of a wet or dry method making it possible to remove a deposited material.
Planarization or planishing: this is a method making it possible to flatten the reliefs on the top layers of the structure composed of different materials. This step is used to planarize these layers in order to prepare them for the following lithographic steps, thus avoiding the problems of final preparation linked to the variations of depth upon the illumination of the photosensitive resin.

The invention relates to the technological step of planarization by proposing a technique that is an alternative to the techniques of the state of the art and better suited to the systems that have temperature constraints and that require a localized planarization in order, for example, to connect microstructures separated by surfaces having positive or negative reliefs. Reliefs are understood to be variations of the height (or of the altitude) of the upper planes, starting from the substrate, of the different structures belonging to the system being fabricated.

The techniques that are currently used to perform the technological step of planarization presents several drawbacks which affect the performance of the fabricated integrated system. The production of such architectures requires the implementation of several technological steps inducing, in each step, additional thermal budgets and not making it possible to planarize objects of different heights in a single step.

As an example, the development of new plasmonics devices for the mid-infrared (optical antennas, resonators) coupled to the traditional architectures (laser, detectors, modulators) brings new technological perspectives but also makes it necessary to review certain fabrication methods. These optical architectures impose constraints in the choice of the materials and their environment.

In this sense, several problems have been clearly identified with the standard fabrication techniques of the state of the art. The metals preferred for these components have a tendency to diffuse through the structures during the heat treatments in the course of the fabrication method, hence the interest in limiting the thermal budget to mitigate this diffusion problem. In addition, the plasmonics structures are highly sensitive to their environment from an optical point of view. So as not to affect the performance levels of the system, it is desirable to limit any optical interaction between the photodetector layers of the component and the external metallic interconnects.

We will begin by introducing the different planarization techniques known to the person skilled in the art.

The first technique is the chemical-mechanical polishing technique (CMP, the acronym for chemical-mechanical planarization). It consists in depositing a layer of dielectric material over all of the surface of the wafer comprising the system currently being fabricated. The deposited dielectric layer covers all the structures forming part of the system. Silicon dioxide SiO2 or silicon nitride Si3N4 is generally used. The level of the dielectric layer is then lowered and flattened via a combination of chemical and mechanical (polishing) treatment to obtain a smooth and uniform surface. The level of the surface obtained following this treatment must be equal to the level of the top surfaces of the structures previously covered to be able to connect them by depositing metallic tracks, for example, on the surface of the dielectric layer flattened by the CMP method. The drawbacks of this method are as follows:
Non-localized treatment: The CMP planarization technique necessitates the deposition of a dielectric layer over all of the surface of the wafer thus covering all the structures, even those for which the planarization is not necessary. Moreover, these deposits over an entire plate can be detrimental to the performance of certain optical components in the example of an optical or optoelectronic device. A localized and targeted planarization treatment would make it possible to minimize the disturbances of the other structures unaffected by this treatment, but this is not possible with the CMP planarization technique.
A high thermal budget: The deposition of the dielectric layer on the surface of the plate supporting the device involves a strong thermal budge with a temperature greater than 180° C. with a time that is variable depending on the thickness to be deposited.
Method complexity: Generally, the CMP planarization step is followed by an etching step to remove the excess of deposited dielectric material. That adds additional steps to the method and then makes the overall fabrication method more complex.

The second technique to be able to connect microstructures having different altitudes or being separated by surfaces having reliefs is the fabrication of the connection microstructures of air bridge type. This is a structure based on a metallic track connecting the top surfaces of two microstructures by pressing just on the points of contact of each edge. The term air bridge thus applies. The drawbacks of this method are as follows:
Mechanical fragility: The metallic track which forms the bridge rests only on two bearing points which presents a fragility of the connection structure. In the case of a mechanical break, the electrical connection between the two connected microstructures will be lost which means malfunctioning of the fabricated device.
A high thermal budget: The fabrication of the air bridge structure involves two lithography steps involving a specific sacrificial layer (PMGI resin). That requires thermal annealings with a high thermal budget ranging up to three minutes at a temperature of 190° C.

The third technique that can be envisaged according to the state of the art is the growth of a support made of a semiconductor material by epitaxy. The metallic connection tracks are then deposited on the support obtained by epitaxy. In the case of an optical support comprising active elements based on semiconductor material, this technique presents the drawback of increasing the generation of noise and/or of undesirable dark current. Furthermore, this technique is detrimental to the electromagnetic performance levels of an optical resonator because the dielectric constant of a semiconductor material is higher than that of the dielectric materials.

The US patent application US 2013/0320470 A1 describes a photodetector device comprising a plurality of optical resonators. The fabrication method described by the patent comprises a planarization step performed by a global deposition of a dielectric layer over all the surface of the plate. This is a non-localized treatment with a high thermal budget.

The publication by C. Maddalon et al., entitled “Planarization properties of HSQ, influence on CMP” describes a technique of planarization of structures (aluminum lines) by a resin comprising hydrogen silsesquioxane (HSQ). In the publication cited, the HSQ resin is spread over all of the surface without being insolated. The drawback of the solution described by Maddalon is the need to add additional CMP polishing or physical etching steps to connect structures separated by reliefs or having different heights.

The publication by C. Choi et al., entitled “Planarization of patterned magnetic recording media to enable head flyability” describes a technique of planarization of a magnetic device. The drawback of the solution described by this article is limiting the planarization between structures having the same height.

### Response to the Problem and Solution Provided

To mitigate the limitations of the existing solutions with respect to the performance of a technological step of planarization making it possible to connect microstructures having different heights or separated by surfaces having positive or negative reliefs, the invention proposes a localized planarization method that is versatile, simple and has low thermal budget. The method according to the invention makes it possible to fabricate a connection microstructure comprising a support made of a dielectric material and a metallic layer resting on said support. The method according to the invention makes it possible to fabricate a support by insolation of a resin via a lithography. More particularly, the application of an electron beam lithography to a negative, inorganic and electrically insulating resin such as hydrogen silsesquioxane HSQ makes it possible to perform a planarization (or planishing) via a method that is better suited to the fabrication of emergent devices whose performance and robustness are affected by the standard planarization techniques that present the drawbacks detailed previously, namely the non-localization, the high thermal budget, the complexity and the mechanical fragility.

### SUMMARY OF THE INVENTION

The subject of the invention is a method for fabricating a device produced on a substrate in a first semiconductor material, the fabrication method comprising the following steps:
i—fabricating at least one first microstructure and one second microstructure on the substrate,
ii—fabricating a connection microstructure making it possible to electrically connect at least the first microstructure to the second microstructure by:
   Depositing a layer of an inorganic resin solution distributed over the substrate.
   Heating the device to a heating temperature for a determined time to evaporate the solvent from the deposited resin solution.
   Fabricating a support in a dielectric material by solidifying, by means of a lithography method, a part of the deposited resin layer, the support comprising at least a first part linking the first microstructure and the second microstructure.
   Depositing a first metallic layer on at least a part of the support comprising at least said first part linking the first microstructure and the second microstructure.

According to a particular aspect of the invention, the deposited resin is an electrically insulating and/or negative resin.

According to a particular aspect of the invention, the deposited resin is an electrosensitive resin and the step of fabrication of the support is performed by electron beam lithography.

According to a particular aspect of the invention, the deposited resin is an HSQ resin comprising hydrogen silsesquioxane.

According to a particular aspect of the invention, the deposited resin reacts to an electron beam insolation such that the thickness of a solidified part of the resin in the step of fabrication of the support depends on the energy dose received by the resin exposed to the electron beam. The support comprises a second part having a surface with a gradual thickness variation produced by varying the dose of the electron beam.

According to a particular aspect of the invention, the first metallic layer (12) is deposited also on the second part to connect a second metallic layer to an electrode having a height that is different from that of the second metallic layer starting from the substrate.

According to a particular aspect of the invention, the heating temperature is less than 100° C. and the heating time is less than 2 min.

According to a particular aspect of the invention, the first microstructure and the second microstructure are optical resonators; the fabrication step i) comprises the following substeps:
i.1 assembling, on the substrate produced by the first semiconductor material, a previously fabricated sample comprising a layer made of a second semiconductor material resting on a reflective metallic layer, the assembly interface being on the side of the reflective metallic layer.
i.2 depositing, for each of the resonators, a first metallic layer on the layer of the second semiconductor material.
i.3 selectively etching the second semiconductor material to produce a photodetector structure for each of the resonators; the photodetector structure being contained between the reflective metallic layer and the first metallic layer.

The subject of the invention is also a device produced on a substrate made of a first semiconductor material. The device comprises a first microstructure, a second microstructure and a connection microstructure making it possible to electrically connect the first microstructure and the second microstructure. The connection microstructure comprises a support made of dielectric material and a metallic layer deposited on said support. The surface covered by the support is strictly less than the surface of the substrate.

According to a particular aspect of the invention, the optoelectronic device comprises at least one pixel (Pxl). The first microstructure and the second microstructure are optical resonators belonging to a same pixel and each optical resonator comprises:
a photodetector structure produced in a second semiconductor material or in a stack of a plurality of layers of semiconductor materials,
a first metallic layer,
and a second, reflective metallic layer (M2).

The photodetector structure is contained between the first metallic layer and the second, reflective metallic layer. The two optical resonators are electrically connected by the connection microstructure.

### BRIEF DESCRIPTION OF THE DRAWINGS

Other features and advantages of the present invention will become more apparent on reading the following description in relation to the following attached drawings.

FIG. 1 illustrates a diagram of two optical resonators incorporated in an optoelectronic device.

FIG. 2 represents the steps of fabrication of an example of an intermediate structure in the fabrication of an optoelectronic device requiring a planarization submethod.

FIG. 3 represents the substeps for performing the technological step of deposition of “lift-off” type.

FIG. 4 represents an embodiment of the fabrication method comprising steps of planarization of the optoelectronic device of FIG. 2 according to the invention.

FIG. 5a represents a cross-sectional view of two optical resonators connected following the execution of the planarization method according to the invention.

FIG. 5b represents a top view of two optical resonators connected following the execution of the planarization method according to the invention.

FIG. 5c represents a perspective view of a part of the optoelectronic device obtained following the execution of the planarization method according to the invention.

FIG. 6a represents a top view of an example of an optoelectronic device comprising several pixels obtained following the execution of the planarization method according to the invention.

FIG. 6b represents a top view of an example of an optoelectronic device comprising a single pixel obtained following the execution of the planarization method according to the invention.

### DETAILED DESCRIPTION

The invention proposes a method for microelectronic and/or microtechnical fabrication of a hybrid or homogeneous structure making it possible to perform a planarization step that is localized and at low temperature based on a dielectric structure supporting metallic contacts.

To illustrate the method according to the invention, the application of the technological step of planarization according to the invention for fabricating a hybrid optoelectronic device will be described by way of example. More particularly, it concerns an infrared detector comprising a matrix of pixels composed of at least one pixel, each pixel comprising a plurality of optical resonators connected to one another. The infrared detector device described represents a hybrid system because the matrix of pixels (forming the optical part of the system) is associated with a read circuit incorporated in a semiconductor substrate (forming the electronic part of the system).

The description of the fabrication and of the structure of this system is given as an indication, and the planarization technique according to the invention is compatible for the fabrication of other structures in the field of microelectronics and microtechnology more generally.

A new generation of components of micro-optic type has recently emerged, founded on an optical transposition of the phenomenon of radiation from an antenna, hitherto implemented for the microwave domain. Resonators, with a size of the order of magnitude of a wavelength, typically plasmonic antennas, re-emit (radiate), from an incident wave, a light exhibiting a resonance wavelength, by modification of the phase of the incident wave. This modification is not performed during a propagation of a light ray as is the case conventionally, but abruptly. The term “metasurface” then applies. It should be noted that this physical principle differs from that of the effective index, in which the phase is also imprinted during the propagation along an optical path by elements of sub-wavelength dimension.

An incident photon on a point of the micro-optic structure is picked up by a precise nano-antenna, interacts therewith, and is re-emitted with a given phase. Each nano-antenna interacts with the incident wave by imprinting on it a phase modulation, and/or amplitude modulation and/or polarization modulation. The arrangement of these resonators makes it possible to model the incident wavefront in order to ensure the desired optical function, which opens up a vast field of wavefront engineering.

The resonator can be of MIM (metal/insulation/metal substrate) or more generally conductor/insulation/substrate type operating in reflection mode, or of dielectric type (on dielectric substrate), operating in reflection mode or in transmission mode.

Each resonator is a radiating dipole or a Huygens dipole (Huygens metasurface) and a significant number of antenna modes are accessible by acting on the form, the size and the arrangement of these dipoles.

It is the interferences between these different antenna modes (for example electrical and magnetic dipolar/quadripolar resonance) which are adjusted to be constructive to the front and destructive to the rear (operating in transmission mode), or conversely constructive to the rear and destructive to the front (operating in reflection mode). The engineering of these resonances and of their radiation patterns confer a large number of degrees of freedom for the modeling (spatial and spectral) of the incident wavefront).

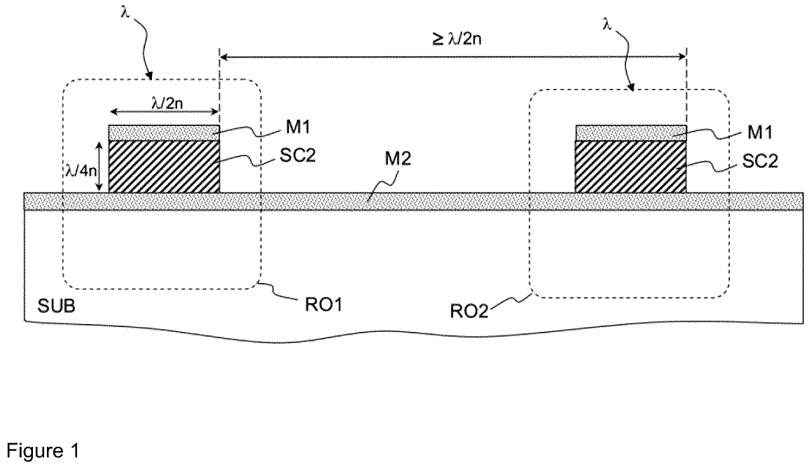

FIG. 1 illustrates a diagram of two optical resonators incorporated in an example of an optoelectronic device obtained by the method according to the invention.

The optical resonators RO1 and RO2 presented in FIG. 1 rest on a substrate SUB made of semiconductor material. At this stage, the representation will be limited to the substrate SUB to simplify the representation, but the volume of the part on which the two resonators RO1 and RO2 rest generally comprises other microstructures which form part of the assembly of the hybrid optoelectronic device OPT. As an example, all of the resonators forming the optical part of the hybrid device are assembled with a silicon wafer, itself comprising the electrical part of the device, namely an integrated microelectronic circuit for reading the signals generated by the photo charge carriers generated by the different resonators.

Each optical resonator RO1 or RO2 comprises a photodetector structure produced in a second semiconductor material SC2 and defining a mesa, a first metallic layer M1 and a second, reflective metallic layer M2. The photodetector mesa structure SC2 is contained between the second, reflective metallic layer M2 and the first metallic layer M1.

“Mesa” is understood to mean a microstructure or nanostructure corresponding to a volume resting on a plane and having a flat top surface.

Alternatively, it is possible to produce the photodetector structure with a semiconductor heterostructure having a refractive index gradient.

The photodetector structure SC2 serves as a phototonic cavity in the optical resonator RO1 (or RO2). This structure is produced via a material of type III-V such as, for example, gallium arsenide, indium arsenide, gallium nitride, gallium antimonide, boron phosphide. The photodetector layer (or structure) SC2 rests on the reflective metallic layer M2 acting as mirror.

Alternatively, it is possible to produce the photodetector structure with ternary or quaternary or quinary alloys or a photodetector layer having an N doping gradient.

Alternatively, it is possible to produce the photodetector structure of an optical resonator RO1 (or RO2) with a stack of a plurality of layers composed of different semiconductor materials thus forming a photodetector heterostructure. The semiconductor materials used for the production of the stack of photodetector heterostructure layers are of type III-V such as, for example, gallium arsenide, indium arsenide, gallium nitride, gallium antimonide, boron phosphide. Furthermore, it is possible to produce the photodetector heterostructure via ternary or quaternary or quinary alloys or photodetector layers having an N doping gradient.

Generally, the reflective layer M2 is common to all the optical resonators RO of the hybrid device OPT being electrically connected to the electrical ground of the device.

The association of the reflective metallic layer M2 with the first, top metallic layer M1 defines a sub-wavelength nano-antenna for an optical resonator as described in FIG. 1. The top metallic layer M1 is deposited on the visible surface of the photodetector mesa SC2. The nanometric scale dimensioning of the resonator RO allows it to absorb particular modes of an incident wave on the side of the top layer of M1. The incident wave having a wavelength A is within the range of the infrared or THz wavelengths.

As an indication, the reflective layer M2 and the top layer M1 can be produced with gold (Au) having a layer thickness that varies, for example, between 25 nm and 500 nm for the reflective layer M2 and a layer thickness that varies, for example, between 150 nm and 1000 nm for the top layer M1.

Advantageously, if n designates the refractive index of the material of the photodetector mesa SC2, the resonator RE2 (or RES3) is dimensioned as follows: at least one dimension of a resonator (and therefore of the top layer M1 and of the photodetector structure SC2), chosen from among the width or the length, lies within the interval [λ/2n−50%; λ/2n+50%]. The thickness of the photodetector layer SC2 is less than λ/2n. For example, the thickness of the photodetector layer SC2 can lie within the interval [λ/4n−50%; λ/2n+50%]. Furthermore, the distance separating two adjacent optical resonators is greater than λ/2n.

Generally, there is no maximum limit on the thickness of the metallic layers used other than a constraint on the thickness of the top layer M1 linked to the diffraction. The low limit of the thickness is generally defined by the skin depth.

These dimensioning intervals make it possible to produce the operation of the resonator by the microstructures RO1 and RO2 described previously. Indeed, each of the resonators intensifies the light-material coupling between the cavity mode TMO and the photosensitive layer SC2, making it possible to intensify the response of the technologies with low quantum efficiency, such as the quantum well inter-subband detectors (QWIPs and QCDs) or the II-VI colloidal quantum boxes (CQD).

When the resonator RO is resonant, the light is then guided and concentrated in the photodetector cavity SC2, making it possible to guarantee an optimal modulation transfer function (MTF), by reducing (even completely eliminating) the phenomena of optical and electrical crosstalk between the resonators. Given that, in the hybrid device OPT, each pixel corresponds to one or more resonators connected to one another, the structure described by FIG. 1 then makes it possible to reduce the pixel pitch to its ultimate dimension corresponding to a sub-wavelength pitch. Furthermore, the effective semiconductor volume is much more reduced than in the planar optoelectronic devices. The electrical volume (that of SC2, which is notably the source of the noise) is much smaller than the volume of collection of the photons (originating the signal). Thus, the dark current and noise are reduced in the device OPT comprising the resonators RO1. The result thereof is an improvement of the signal-to-noise ratio. It must be added that this architecture is intrinsically fast because it has a low pixel capacitance.

In a particular embodiment, an optical resonator RO operates as an antenna in which the bottom metallic layer M2 acts as reflective layer and the top metallic layer M1 acts as radiating element of the antenna.

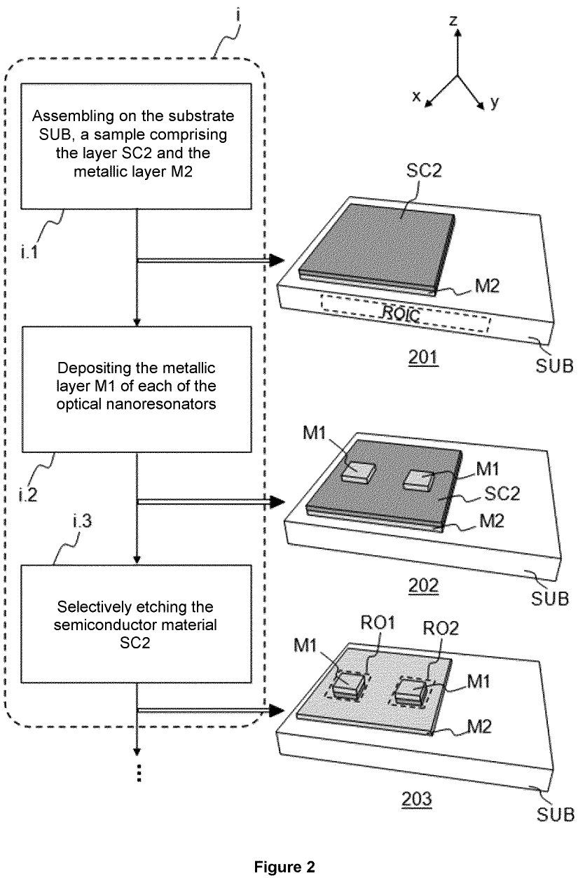

FIG. 2 illustrates the steps of fabrication of the resonators RO1 and RO2 described in FIG. 2 in the fabrication of the optoelectronic device OPT. With no loss of generality, and to simplify the presentation, only the steps of fabrication of two resonators will be presented. More generally, the fabrication steps illustrated by FIG. 2 make it possible to fabricate N optical resonators, with N a strictly positive integer, according to the specifications of the optoelectronic device OPT.

The first step i.1 consists in assembling a sample comprising a second semiconductor material SC2 on the silicon wafer (presented here by substrate SUB). At this stage, only the substrate SUB will be represented to simplify the representation, but the volume of the SUB structure further comprises, in depth, an integrated read circuit ROIC in the wafer based on the substrate SUB. The assembled sample is fabricated prior to this step and comprises a layer of the semiconductor material used for the future photodetector structures SC2 (of III-V type for example) resting on a metallic conductive layer M2 (of Au for example). The common interface between the sample and the substrate SUB (containing the ROIC circuit) is on the side of the visible surface of the metallic layer M2. Thus, after the assembly step i.1, the structure described in the perspective representation 201 is obtained: working from bottom to top along the axis z, what is obtained is the substrate SUB, then the metallic layer M2 then a layer of semiconductor material SC2.

The assembly can be produced by bonding, a fast-developing technique which constitutes a significant advance for the performance of so-called “above IC” technological steps, that is to say steps that can be performed directly on the plate of the read circuit ROIC, typically of CMOS type, and collectively over all the chips. This compatibility with the CMOS fabrication means is suited to a significant lowering of the production costs and the possibility of achieving technological patterns of thinner size.

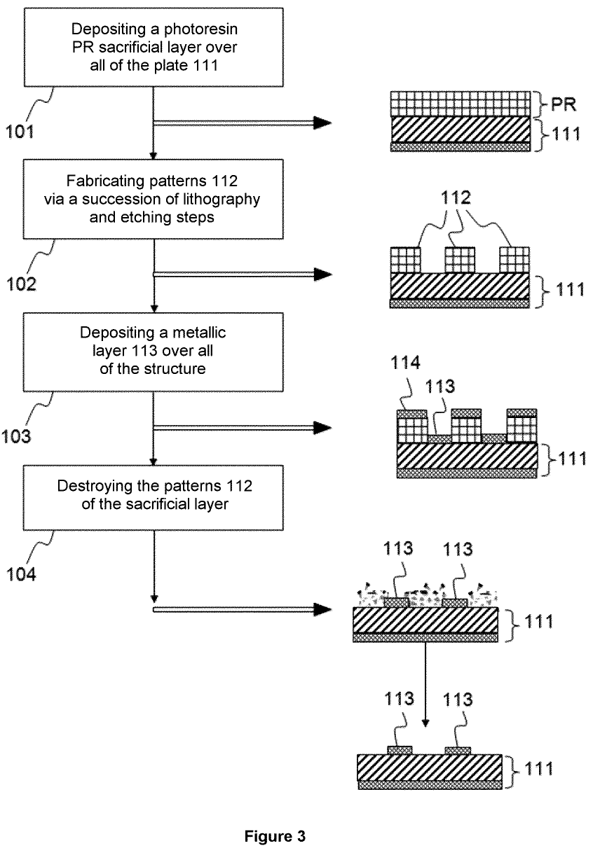

The second step i.2 consists in depositing the metallic layer M1 of each of the optical nano-resonators RO1, RO2 to form the top metallic structures M1 on the layer of the semiconductor material SC2. This step is, for example, performed via a deposition method of “lift-off” type. It is an additive technique used in microtechnology that aims to create patterns of a target material (in the present case, the metallic layers M1) on the surface of a substrate (in the present case, the stack of the layers M2 and SC2) by using a sacrificial material (generally a photosensitive resin). As an indication, the detail of how a deposition of “lift-off” type progresses is described in FIG. 3.

The first substep 101 of a deposition of “lift-off” type consists in depositing a sacrificial layer of photoresin PR over all of the plate 111 which comprises a stack of layers. Next, the second substep 102 consists in fabricating patterns 112 in the sacrificial layer PR via a succession of steps of lithography and of etching or of revelation in a solvent. The third substep 103 consists in depositing a metallic layer over all of the plate 111 so as to obtain metallic layers 114 deposited on the structures 112 but also layers 113 between the structures 112 directly on the visible surfaces of the stack of layers 111. The last substep 104 consists in destroying the patterns 112 by a chemical method making it possible to keep only the metallic layers 113 deposited directly on the stack 111. Thus, the compilation of the substeps 101, 102, 103 and 104 makes it possible to perform the step i.2 of deposition of the metallic layer M1 of each of the optical nanoresonators RO1, RO2 on the layer of the semiconductor material SC2.

The result of the step i.2 is illustrated by the structure described in the three-dimensional representation 202 in which the square patterns M1 deposited on the layer of semiconductor material SC2 can be observed.

The third step i.3 consists in selectively etching the semiconductor material SC2 to keep only the parts covered by the patterns M1 deposited during the step i.2. As an example, this step can be performed via a physical etching technique of ICP (inductively coupled plasma) type. This is a dry etching technique based on a plasma torch system.

The result of the step i.3 is illustrated by the structure described in the representation 203: the structure of the optical resonators RO1 and RO2 each comprising a photosensitive mesa of semiconductor material SC2 (cavity of the resonator), a top metallic layer M2 and a reflective metallic layer M2 (mirror of the resonator) is obtained that is common to all the optical resonators. The set of the resonators forms the optical part of the hybrid system assembled with the electronic part consisting of a read circuit ROIC incorporated in a silicon substrate SUB. When assembled, the optical part (RO1, RO2) and the electronic part (ROIC) form the hybrid optoelectronic device OPT.

The optoelectronic device OPT comprises at least one pixel Pxl based on the resonators previously described. In one embodiment, a pixel Pxl comprises a single resonator such that the metallic layer M1 is connected to a buried electrode of the read circuit ROIC and the reflective metallic layer M2 common to all the pixels is connected to the electrical ground.

One drawback of a single-resonator pixel lies in the low signal intensity generated by the pixel which can create detection difficulties. Furthermore, it is difficult to focus an infrared incident beam on a single resonator.

Alternatively, it is possible to produce a pixel Pxl comprising a plurality of resonators thus making it possible to increase the intensity of the signal detected by collecting all of the beam by a network of resonators. Thus, a pixel comprises a plurality of resonators (RO1, RO2) such that all the top metallic layers M1 of all of the resonators belonging to a same pixel are connected to one another.

This presents a technological challenge because the resonators fabricated as described previously are separated by surfaces that have positive or negative reliefs and different heights. That renders the technological step of planarization necessary to be able to deposit metallic tracks connecting the different layers M1 belonging to a single pixel Pxl.

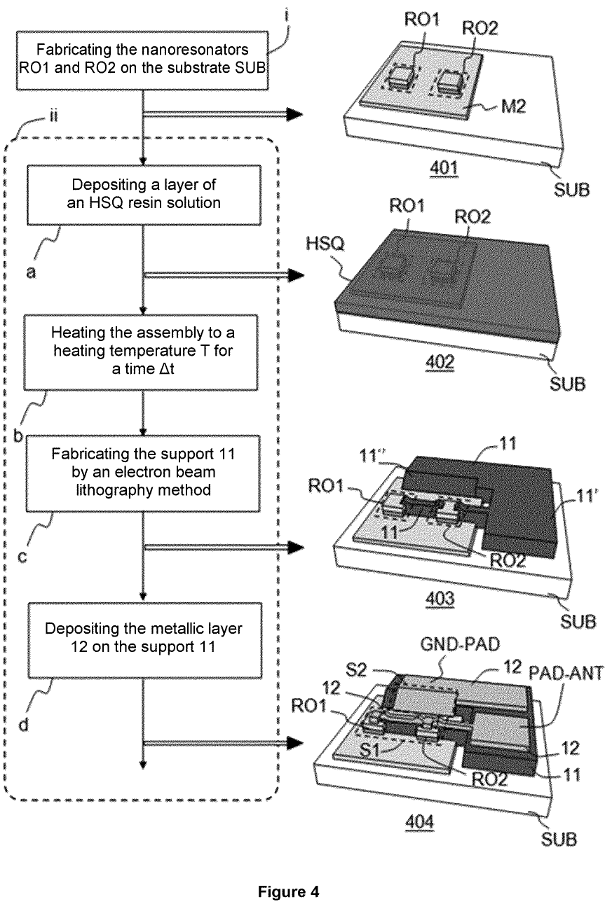

It is in that particular context that the technical benefit of the planarization method according to the invention illustrated by FIG. 4 is manifested. Thus, one objective of the fabrication method according to the invention presented hereinbelow is the fabrication of a connection microstructure making it possible to electrically connect at least one second microstructure (in this case, the resonator RO1) to a third microstructure (in this case, the resonator RO2). Before the execution of the planarization steps, the second microstructure RO1 and the third microstructure RO2 are separated by at least one positive or negative relief with respect to one of the microstructures to be connected.

The first step i of the microtechnical fabrication method according to the invention consists in fabricating the resonators on the substrate SUB as detailed previously. The structure illustrated in 401 is thus obtained.

The second step iia consists in depositing a layer of a resin solution uniformly distributed over the semiconductor substrate, for example, by a spin coating method. Advantageously, and with no loss of generality, the resin used has the following characteristics:
Electrosensitive: to be able to plot the desired patterns using an electron beam lithography allowing a localized treatment and control of the height of the structures obtained by insolation.
Negative to be able to plot the patterns upon insolation. It is also possible to envisage a positive resin although the lithography is much slower.
Inorganic to withstand the following technological steps of the general fabrication method involving chemical treatments using solvents. Furthermore, an inorganic resin is less absorbent in the infrared than an organic resin. That makes it possible not to attenuate the performance levels of the optical resonators.
Electrically insulating to avoid the risks of short circuit.
Versatile for planarizing surfaces having positive or negative reliefs. That allows it to be applied to a varied range of heights of objects in a single step and thus simplify the method.

A resin comprising hydrogen silsesquioxane HSQ has all of these characteristics.

By comparing the resin HSQ to the resin PMGI commonly used for the fabrication of air bridges, several advantages of the resin HSQ have been observed that make its choice of use more pertinent. Indeed, the resin PMGI is organic, its cross-linked form is not mechanically solid and it exhibits a high rate of absorption of the infrared rays attenuating the performance levels of the optical resonators.

The method is not limited to this type of resin and other inorganic resins can be envisaged by adapting the method with the characteristics of the resin that is chosen. For example, it is possible to use a photosensitive resin in the case where a photonic lithography is used for the insolation.

The third step iib consists in performing a thermal annealing of all of the structure covered by the solution containing the deposited resin to evaporate the solvent. This step necessitates a very low thermal budget compared to the planarization techniques of the state of the art. Indeed, the heating step iib in the method according to the invention is performed at only 80° C. for 1 minute for the pre-insolation annealing. That offers a considerable advantage compared to the planarization techniques of the state of the art such as CMP requiring a heat treatment at 180° C. for a few minutes.

The fourth step iic consists in fabricating the support of dielectric material 11 via a lithography operation. By using an HSQ resin, an electron beam lithography allows a localized insolation of the HSQ layer. Under the action of the exposure to the electron beam, the HSQ resin is crosslinked to have a structure similar to a dielectric in the solid state and, more particularly, silicon dioxide SiO2. It is then possible to plot with nanometric accuracy solid patterns from the layer of HSQ. The association of an HSQ resin with electron beam lithography also offers a significant advantage. By controlling the dose of exposure of the HSQ to the electrons, it is possible to vary its thickness after revelation. That makes it possible to locally adjust the support height 11 to adapt to the various reliefs of the sample. Following the phase of insolation of the resin and the solidification of the patterns which form the support 11, the parts of the deposited resin that are not solidified are removed from the surface of the wafer to keep only the cross-linked solid parts of the resin.

As an indication, after the step iic, the structure of the support 11 illustrated in 403 is obtained. In the demonstrative case of fabrication of an optoelectronic device OPT, the succession of the steps i to iic makes it possible to fabricate the support 11 linking the layer M1 of the optical resonator RO1 to that of the optical resonator RO2.

Furthermore, the support 11 comprises a layer 11′ having the same height as that of the top layers M1 of RO1 and RO2 and linked to the top layer M1 of any one of the optical resonators belonging to the same pixel. The top surface of the layer 11′ will serve as support for a global electrode of the resonators PAD_ANT.

Furthermore, the support 11 comprises a layer 11″ having a surface with height difference with an altitude which increases gradually from the level of the reflective layer M2 to reach a plateau at a greater height. Said plateau will serve as support for a global electrode of the reflective layer denoted GND_PAD.

The next step iid consists in depositing the metallic layer 12 on the support 11 to electrically connect the top layers M1 of the resonators RO2 and RO1 but also to fabricate the global ground electrode GND_PAD connected to the reflective layer M2 and fabricate the global antenna electrode PAD_ANT connected to a top layer M1 of at least one of the optical resonators belonging to the pixel Pxl as presented in 404. With no loss of generality, the step iid can be performed by a deposition technique of “lift-off” type described in FIG. 3.

Thus, the method described by FIG. 4 makes it possible to perform a planarization that offers the following advantages over the techniques of the state of the art: versatile, localized, low thermal budget, simple and allowing a freedom of design according to the characteristics of the resin that is chosen.

This method is more suited to the fabrication of emergent devices whose performance and robustness are affected by the standard planarization techniques that have the drawbacks detailed previously, namely the fact that the planarization is global, the high thermal budget, the complexity and the mechanical fragility.

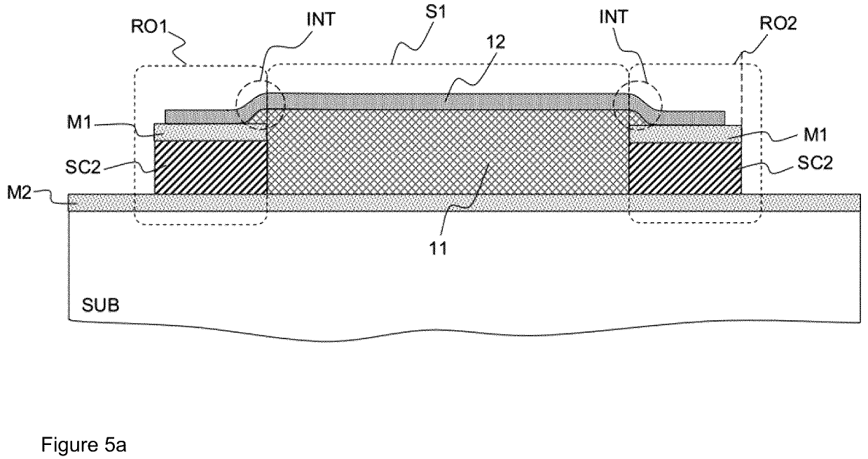

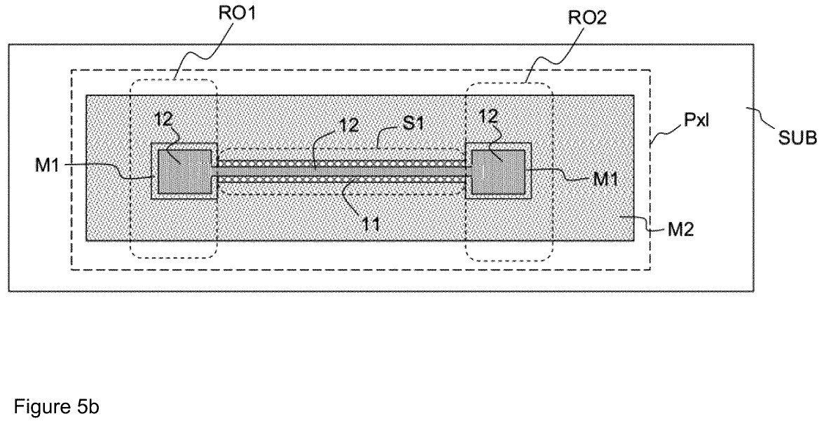

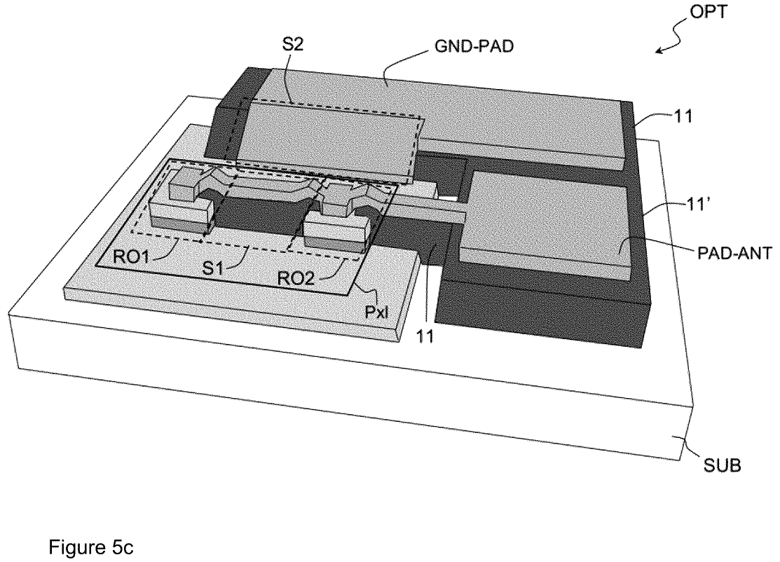

FIG. 5a represents a cross-sectional view of the two resonators RO1 and RO2 connected by the method according to the invention via the microstructure S1 resulting from said planarization method. The connection microstructure S1 is composed of a part of the support 11 made of dielectric material (in this case HSQ cross-linked by electron beams) and a part of the layer 12 deposited in the step iid. The height of the support 11 exceeds, by a few tens of nanometers, the height of the resonators RO1 and RO2. This choice of design makes it possible to fabricate a part of the support 11 which partially and in a limited way covers the surface of each of the top layers M1 to be connected at the adjacent edge of the support 11 as indicated in FIG. 5a by the zone INT. That adds mechanical and electrical robustness to the microstructure S2 by reinforcing the connection points with the layers M1. This microengineering step necessitates fabrication accuracy which is not offered by the solutions of the state of the art. This level of accuracy for controlling the height of the support 11 in a localized manner is ensured by modulation of the height of the HSQ patterns during insolation by an electron beam.

FIG. 5b represents a top view of a pixel Pxl comprising two resonators RO1 and RO2 connected by the method according to the invention via the microstructure S1 resulting from said planarization method. The connection microstructure S1 is composed of a part of the support 11 made of dielectric material (in this case HSQ cross-linked by electron beams) and a part of the layer 12 deposited in the step v.

FIG. 5c represents a perspective view of a part of the optoelectronic device OPT obtained by the method according to the invention. The pixel Pxl composed of the two resonators RO1 and RO2 connected via the microstructure S1 can be seen. Also illustrated is the global ground electrode GND_PAD connected to the reflective layer M2 via a microstructure S2 having a surface with a gradual altitude variation. Also illustrated is the global electrode PAD_ANT resting on a plateau 11′ of the support 11 and connected to at least one of the structures M1 of the pixel Pxl.

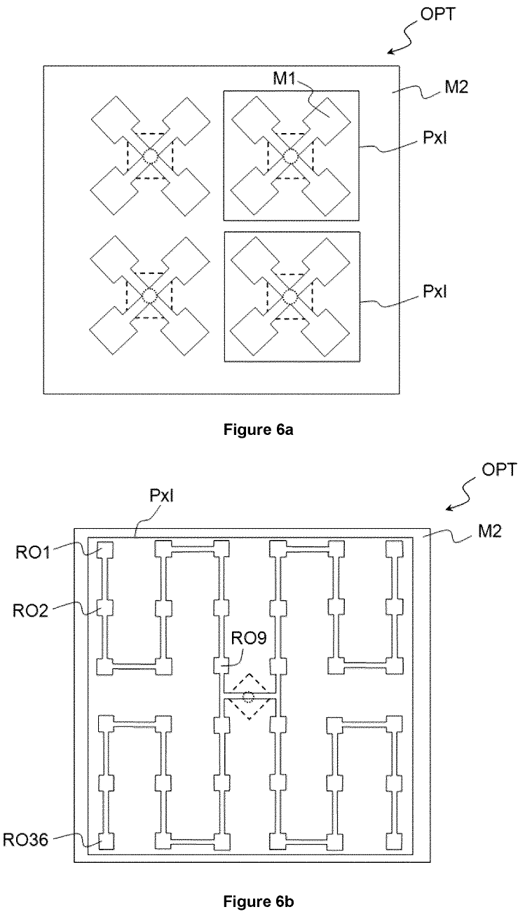

FIGS. 6a and 6b illustrate alternative embodiments of an optoelectronic device OPT comprising at least one pixel Pxl. In FIG. 6a, 4 pixels are illustrated such that each comprises 4 optical resonators. The four resonators are connected via a connection microstructure in the form of a star produced by the fabrication method according to the invention. FIG. 6b illustrates an example of an optoelectronic device comprising a single pixel composed of 36 optical resonators connected to one another via a microstructure produced by the planarization method according to the invention.

In conclusion, the invention described makes it possible to perform a fabrication method from the technology of a hybrid device produced on a support composed of a substrate comprising a planarization sub-method making it possible to connect at least two structures separated by a surface having at least one negative or positive relief. The method according to the invention offers an interesting alternative to the techniques of the state of the art such as CMP or air bridge because it makes it possible to perform a localized planarization step, with low thermal budget and that is compatible with the different reliefs present on the surface to be planarized.

1. A method for fabricating a device (OPT) produced on a substrate in a first semiconductor material (SUB);
the fabrication method comprising the following steps:
i—fabricating at least one first microstructure (RO1) and one second microstructure (RO2) on the substrate (SUB),
ii—fabricating a connection microstructure (S1) making it possible to electrically connect at least the first microstructure (RO1) to the second microstructure (RO2) by:
depositing a layer of an inorganic resin solution distributed over the substrate (SUB);
heating the device to a heating temperature (T) for a determined time (Δt) to evaporate the solvent from the deposited resin solution;
fabricating a support in a dielectric material by solidifying, by means of a lithography method, a part of the deposited resin layer; the support comprising at least a first part linking the first microstructure (RO1) and the second microstructure (RO2);
depositing a first metallic layer on at least a part of the support comprising at least said first part linking the first microstructure (RO1) and the second microstructure (RO2).

2. The method for fabricating a device (OPT) as claimed in claim 1, wherein the deposited resin is an electrically insulating and/or negative resin.

3. The method for fabricating a device (OPT) as claimed in claim 2, wherein the deposited resin is an electrosensitive resin and wherein the step of fabrication of the support is performed by electron beam lithography.

4. The method for fabricating a device (OPT) as claimed in claim 3, wherein the deposited resin is an HSQ resin comprising hydrogen silsesquioxane.

5. The method for fabricating a device (OPT) as claimed in claim 3, wherein the deposited resin reacts to electron beam insolation such that the thickness of a solidified part of the resin in the step of fabrication of the support (41 depends on the energy dose received by the resin exposed to the electron beam;
and wherein the support comprises a second part having a surface with a gradual thickness variation produced by varying the dose of the electron beam.

6. The method for fabricating a device (OPT) as claimed in claim 5, wherein the first metallic layer is deposited also on the second part to connect a second metallic layer (M2) to an electrode (GND_PAD) having a height that is different from that of the second metallic layer (M2) starting from the substrate (SUB).

7. The method for fabricating a device (OPT) as claimed in claim 1, wherein the heating temperature (T) is less than 100° C. and the heating time (Δt) is less than 2 min.

8. The method for fabricating an optoelectronic device (OPT) as claimed in claim 1, wherein the first microstructure (RO1) and the second microstructure (RO2) are optical resonators; the fabrication step i) comprises the following substeps:
i.1 assembling, on the substrate (SUB) produced by the first semiconductor material, a previously fabricated sample comprising a layer made of a second semiconductor material (SC2) resting on a reflective metallic layer (M2), the assembly interface being on the side of the reflective metallic layer (M2);
i.2 depositing, for each of the resonators (RO), a first metallic layer (M1) on the layer of the second semiconductor material (SC2);
i.3 selectively etching the second semiconductor material (SC2) to produce a photo-detector structure for each of the resonators; the photo-detector structure (SC2) being contained between the reflective metallic layer (M2) and the first metallic layer (M1).

9. A device (OPT) produced on a substrate in a first semiconductor material (SUB), the device (OPT) comprising a first microstructure (RO1), a second microstructure (RO2) and a connection microstructure (S1) making it possible to electrically connect the first microstructure (RO1) and the second microstructure (RO2);
the connection microstructure (S1) comprising:
a support made of a dielectric material composed of a solidified inorganic resin, and a metallic layer deposited on said support;
the surface covered by the support being strictly less than the surface of the substrate (SUB).

10. The optoelectronic device (OPT) as claimed in claim 9, comprising at least one pixel (Pxl); wherein the first microstructure (RO1) and the second microstructure (RO2) are optical resonators belonging to a same pixel, each optical resonator (RO1, RO2) comprising a photodetector structure produced in a second semiconductor material (SC2) or in a stack of a plurality of layers made of semiconductor materials, a first metallic layer (M1) and a second, reflective metallic layer (M2); the photodetector structure (SC2) being contained between the first metallic layer (M1) and the second, reflective metallic layer (M2), the two optical resonators being electrically connected by the connection microstructure (S1).
